(19) United States
(12) Patent Application Publication
(10) Pub. No.: US 2019/0049077 A1
(43) Pub. Date: Feb. 14, 2019

(54) Flexible Power Distribution System

(71) Applicant: Elemental LED, Inc., Reno, NV (US)

(72) Inventors: Jeffrey F. Corvese, Marshfield, MA (US); Andrew Flesher, Oakland, CA (US); Andrew McAleavey, Reno, NV (US); Anthony Thomas, Sparks, NV (US); Olivia M. Tanguileg, Reno, NV (US); Andrew Lassen, Reno, NV (US)

(21) Appl. No.: 16/101,342

(22) Filed: Aug. 10, 2018

Related U.S. Application Data
(60) Provisional application No. 62/544,653, filed on Aug. 11, 2017.

(51) Int. Cl. F21S 4/24; F21V 21/08; F21V 23/06; H05K 1/18; F21V 21/005

(52) U.S. Cl. CPC F21S 4/24; F21V 21/0808; F21Y 2103/10; H05K 1/189; F21V 21/005; F21V 23/06

(57) ABSTRACT

A flexible power conductor strip is disclosed. The power conductor strip comprises an elongate, flexible printed circuit board that carries a pair of conductors. Connectors are mounted on the power conductor strip at a regular pitch or spacing and are electrically connected to the pair of conductors. The flexible printed circuit board is arranged such that it can be physically cut into independent functional units, each of the independent functional units including some connectors.

### CROSS-REFERENCE TO RELATED APPLICATIONS

This application claims priority to U.S. Provisional Patent Application No. 62/544,653, filed Aug. 11, 2017. The contents of that application are incorporated by reference in their entirety.

### BACKGROUND OF THE INVENTION

### 1. Field of the Invention

In general, the invention relates to flexible power distribution systems, and more particularly, to flexible power distribution systems for powering lighting fixtures.

### 2. Description of Related Art

Over the last decade, lighting based on light-emitting diodes (LEDs) has become dominant in the lighting industry and is widely used in both residential and commercial installations. LED-based lighting has a number of advantages compared with legacy incandescent and fluorescent lighting, including high efficiency and low power draw, relatively low operating temperatures, and, with some models, selectable color and a wide variety of available color temperatures.

For most commercial and residential applications, two major types of LED-based lighting are used: bulb-type lamps and linear lighting. Bulb-type lamps are intended as direct replacements for incandescent light bulbs, typically have a shape similar to the type of bulb they are intended to replace, and are usually constructed to produce roughly the same light output as the bulbs they are intended to replace. Linear lighting is somewhat different—it usually includes a number of LEDs arranged at a regular spacing or pitch along a printed circuit board (PCB). That PCB may be rigid, made, for example, of FR4 composite, or it may be flexible, made, for example, of Mylar. In either case, the PCB usually has the form of a thin strip, although other shapes and sizes are possible.

One of the major advantages of linear lighting is its versatility. Alone, it can serve as accent lighting or task lighting, often in locations where it would be difficult to install traditional lighting fixtures. Placed in an appropriate extrusion and covered with a diffuser, it can serve as primary room lighting, replacing legacy fluorescent fixtures in offices. Properly electrically insulated and encapsulated, it can be used even in outdoor and wet locations.

The versatility of LED lighting in general, and linear lighting in particular, creates a problem: supplying power. Most household and commercial power is high-voltage, alternating current (AC) power. Most LED lighting fixtures operate using low-voltage direct current (DC) power. (While the definitions of “low voltage” and “high voltage” depend on the authority one consults, for purposes of this description, voltages over about 50V will be considered to be high voltage.) To convert from high-voltage AC to low-voltage DC, a driver is usually used. Drivers are typically large, bulky components whose size increases with the amount of power they are designed to supply, and finding space for them in any particular installation can be difficult.

In complex installations, providing power can be even more difficult. In some situations, linear lighting may be installed along multiple surfaces, and some independent strips of linear lighting may be far from the driver that is intended to power them. U.S. Pat. No. 9,404,645, which is incorporated by reference in its entirety, deals with this problem in the context of gondola shelving units. That patent describes a set of at least semi-rigid printed circuit boards (PCBs) with surface-mounted connectors.

### SUMMARY OF THE INVENTION

One aspect of the invention relates to a flexible power connector strip. The flexible power connector strip comprises an elongate, flexible printed circuit board. The printed circuit board defines a pair of connectors, typically on a metallization layer within the printed circuit board. A plurality of connectors are mounted on the flexible printed circuit board. Each of the plurality of connectors is electrically connected to the pair of conductors.

Typically, the power connector strip comprises a plurality of sections of flexible printed circuit board that are soldered together at overlap joints to form the entire length of the power connector strip. In this way, the power connector strip itself may be of arbitrary length. Each of the sections of printed circuit board may have more solder contacts than are necessary for electrical connection such that some of the contacts can be used for alignment purposes. The solder contacts may be concealed. In most embodiments, the power connector strip will have an attachment mechanism, such as adhesive or magnets, on its reverse in order to attach it to a surface.

The connectors may be any type of connector that is mountable on the printed circuit board, either by surface mounting or by another process. The connectors may be male or female. While in most embodiments, each power connector will accept a complementary connector, in some embodiments, the connectors may be terminal blocks or other structures that will accept either bare wire leads or another type of dissimilar connecting structure. While in many embodiments, each of the independent functional units will be identical to the others, such that any connector can be an input connector and any connector can be an output connector, in other embodiments, the functional units may be different, with some specialized for input and others specialized for output. Functional units or other portions of the power connector strip may be connected by thinned, undulating portions to allow the power connector strip to flex in multiple planes.

Other aspects, features, and advantages of the invention will be set forth in the description that follows.

### BRIEF DESCRIPTION OF THE DRAWING FIGURES

The invention will be described with respect to the following drawing figures, in which like numerals represent like features throughout the invention, and in which:

FIG. 1 is a perspective view of a flexible power connector strip according to one embodiment of the invention;

FIG. 2 is a top plan view of the flexible power connector strip of FIG. 1;

FIG. 3 is a side elevational view of the flexible power connector strip of FIG. 1;

FIG. 4 is a perspective view of the flexible power connector strip of FIG. 1, shown on a spool;

FIG. 5 is a perspective view of a flexible power connector strip according to another embodiment of the invention, illustrating a different type of connector in use;

FIGS. 6 and 7 are top plan views of a single unit of a flexible power connector strip capable of bending in multiple planes according to yet another embodiment of the invention;

FIG. 8 is a side elevational view of an encapsulated high-voltage flexible power connector strip according to yet another embodiment of the invention;

FIG. 9 is a circuit diagram of an electrical unit of a flexible power connector strip according to a further embodiment of the invention; and

FIG. 10 is a circuit diagram of a flexible power connector strip with specialized input and output units, according to another further embodiment of the invention.

### DETAILED DESCRIPTION

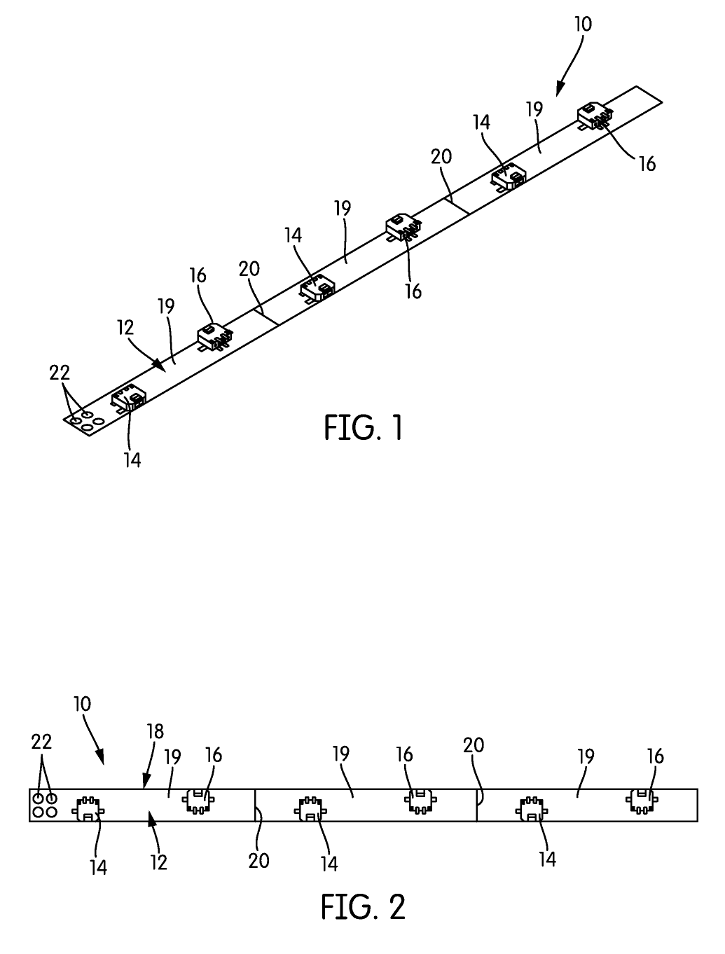

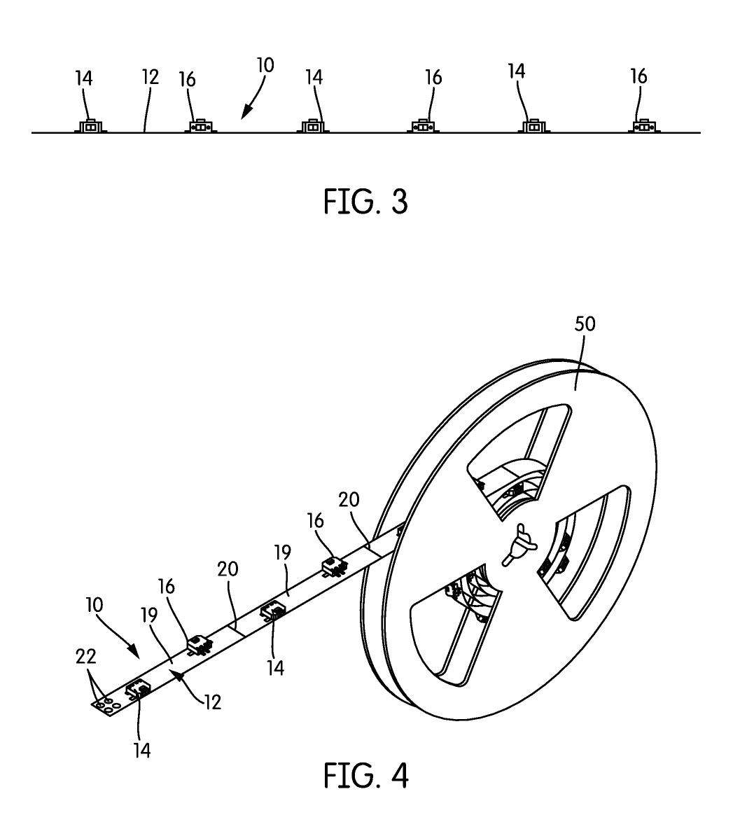

FIG. 1 is a perspective view of a flexible power connector strip, generally indicated at 10, according to one embodiment of the invention, and FIGS. 2 and 3 are top plan and side elevational views, respectively, of the power connector strip 10. The power connector strip 10 comprises a printed circuit board (PCB) 12 on which a plurality of surface-mounted connectors 14, 16 are provided.

The PCB 12 itself is typically thin and elongate (i.e., much longer than it is wide). For example, PCB 12 widths in the range of 10-20 mm may be particularly suitable, depending on the nature of the connectors 14, 16 that are to be mounted. For example, in one embodiment, the PCB 12 may be 14 mm wide. The PCB 12 is also flexible, made, for example, of a material such as Mylar. Of course, Mylar is not the only material from which the PCB 12 may be made—in sufficiently thin section, many materials possess the kind of flexibility that is useful in the power connector strip 10, including thin sections of FR4 (i.e., glass fiber composite), aluminum, polyimide, silicon, gold, carbon nanotubes, and any number of plastics. The PCB 12 may be manufactured using any suitable technique.

The power connector strip 10 may be of any length, ranging from a few centimeters to several meters or more. The only potential limitation on length is the inherent electrical resistance of the PCB 12 and its metallization layers, which causes a voltage drop over extended lengths. If only a single power source is connected at one end of the PCB 12, at some length, the voltage will have dropped to a voltage that is no longer usable. If the power connector strip 10 needs to be run to particularly long lengths (e.g., greater than a few meters), the problem of ohmic voltage drop can be addressed by increasing the amount of conductive material in the strip 10, either by widening the strip 10 to include more conductive material, or by adding additional metalization layers and vias to connect those layers.

The PCB 12 itself is constructed in repeating blocks that are connected together to create a power connector strip 10 of arbitrary length. FIGS. 1-3 illustrate a single repeating block 18. Long, flexible PCB strip is typically made by making a rectangular flexible PCB with standard dimensions, e.g., 300 mm wide by 750 mm long, mounting components on it, and then slicing it into strips. The strips may be 8 mm, 10 mm, 12 mm, or 14 mm, for example. Those slices, with lengths of, e.g., 750 mm, become the repeating blocks 18. In this example, the PCB 12 would have an overlapping joint between two end-to-end repeating blocks approximately every 750 mm.

Each repeating block 18 is divided into units 19. Each unit 19 is a complete electrical circuit unto itself, including several connectors 14, 16 and the circuitry needed to support the connectors 14, 16. In the illustrated embodiment, each unit 19 includes one right-facing connector 14 and one left-facing connector 16. Depending on the application, power connector strips 10 may have connectors facing in other directions or extending along other planes as well. Although the repeating block 18 of the illustrated embodiment includes multiple units 19, each repeating block 18 may include only a single unit 19.

Because each unit 19 is a complete electrical circuit, each unit 19 is separable from the others. In the illustrated embodiment, cut points 20 are marked on the PCB 12 by screen printing or another appropriate technique. The PCB 12 can be physically cut by a knife, scissors, or another appropriate implement to separate the individual units 19. The physical length of one unit 19 is the minimum functional length that the power connector strip 10 can be. As will be described below in more detail, that minimum functional length may vary from one embodiment to another depending on the type and size of connectors 14, 16 that are used, the pitch at which the connectors 14, 16 are spaced, and a number of other factors.

In addition to the cut-points 20 that separate adjacent units 19, each repeating block 18 has a set of conductive contacts 22 that can be soldered or adhered to contacts 22 from other repeating blocks 18 to create a long, continuous power connector strip 10 of arbitrary length. There are four separate contacts 22 in the illustrated embodiment, although there may be more or fewer in other embodiments. These contacts 22 are used to connect adjacent repeating blocks 18 into a single power connector strip 10.

As those of ordinary skill in the art will realize, if the power connector strip 10 carries only power, there need only be two contacts 22—one for power and one for ground or neutral. The presence of four contacts 22 in the illustrated embodiment helps to ensure proper alignment between adjacent repeating blocks 18. Preferably, where a connection is made, the contacts 22 on the upper of the two repeating blocks 18 are covered, so that the joint is not visible from the top on casual inspection. In some cases, this may be used to discourage soldering to the power connector strip 10.

The connectors 14, 16 themselves may be any type of connectors that can be mounted on or connected to the PCB 12. In the illustrated embodiment, the connectors 14, 16 are female surface-mount connectors, but in various embodiments, they may be either male or female. While the connectors 14, 16 are shown on only one side of the PCB 12, in some embodiments, they could be installed on both sides of the PCB 12.

As can be appreciated from FIGS. 1-3, the connectors 14, 16 are arranged at a regular pitch. For example, the connectors 14, 16 may be arranged at a pitch of 2 inches (50.8 mm). The repeating block 18 may be, e.g. 12 inches long, with cut points arranged every 4 inches. Generally speaking, the contacts 22 are arranged such that if a proper joint is made between adjacent repeating blocks 18, the pitch of the connectors 14, 16 will remain the same along the entire power connector strip 10.

The particular pitch at which the connectors 14, 16 are set, the length of the repeating blocks 18, and the interval at which cut points 20 are set may vary widely from embodiment to embodiment. A lesser connector pitch and shorter intervals between cut points 20 may be convenient for end installers, because the resulting power connector strip 10 can be cut more closely to desired lengths (e.g., it can be cut at 1-inch intervals, instead of 4-inches, etc.). Of course, decreasing the length of the repeating blocks 18 may increase the overall cost of the power connector strip 10 commensurately. That said, the only physical lower limit to the length of each repeating block 18 is the size of the connectors 14, 16.

Depending on the embodiment, the power connector strip 10 may have adhesive, magnetic strip, or other such elements on its reverse, in order to facilitate its installation on a surface. Alternatively, in some embodiments, the PCB 12 may be designed and manufactured with openings in it in order to secure nails, screws, and other such fasteners.

With the power connector strip 10 of FIGS. 1-3, a user can plug a driver or other power supply into one connector 14, 16 somewhere along the strip 10, and power can be drawn from any other connector 14, 16 along the strip. Because the power connector strip 10 is flexible, in some applications, it may also serve the purpose of a cable—it can be bent along a surface, and can be used in long lengths. The power connector strip 10 can thus be used as a part of a power distribution system, with strips 10 arranged in a grid, a spoke pattern, or any other desired shape to bring power to lighting fixtures or other elements.

In most embodiments, the power connector strip 10 will carry low voltage, and the connectors 14, 16 will have two separate contacts, for power and ground. However, in some embodiments, the power connector strip 10 and the connectors 14, 16 may have additional contacts for signals. For example, in another embodiment, a power connector strip may carry a 0-10V dimming signal for dimming and control purposes. In that case, additional conductors would be provided on the PCB, and the connectors would be chosen appropriately. It should be understood, however, that the power connector strip 10 is not necessarily limited to low voltage. If the power connector strip 10 carries high voltage (e.g., typical household or commercial voltage), it may be provided with additional layers of insulation, as required by applicable electrical regulatory code.

One particular advantage of power connector strip 10 according to embodiments of the invention is that the flexibility of the power connector strip 10 allows it to be stored and shipped more easily than comparable rigid strips. As one example, FIG. 4 illustrates a spool 50 on which power connector strip 10 is wound for storage and shipping. Power connector strip 10 in lengths of 5 m, 10 m, 15 m or longer may be delivered on spools like spool 50. In some cases, the spool 50 may have a large-diameter core, in order to keep the bending radius to which the power connector strip 10 is exposed relatively large.

FIG. 4 also illustrates the way that power connector strip 10 can bend. In addition its advantages in storage and shipping, the flexibility of power connector strip 10 allows it to bend in actual installation as well. Thus, a single piece of power connector strip 10 can bend around a corner or wrap around a curve, allowing it to be installed along two or more different faces of an object, if needed. As was briefly described above, it may attach to its substrate with adhesive or magnetic tape. Thus, while power connector strip 10 may be put to the same uses as the rigid or semi-rigid strips of U.S. Pat. No. 9,404,645, the flexibility of power connector strip 10 makes it suitable for a plethora of additional applications. For example, if power connector strip 10 is used with flexible LED linear lighting, power connector strip 10 can go anywhere that the LED linear lighting can go. (U.S. Pat. No. 10,024,526, the contents of which are incorporated by reference in their entirety, describes and illustrates one embodiment of flexible low-voltage linear lighting.)

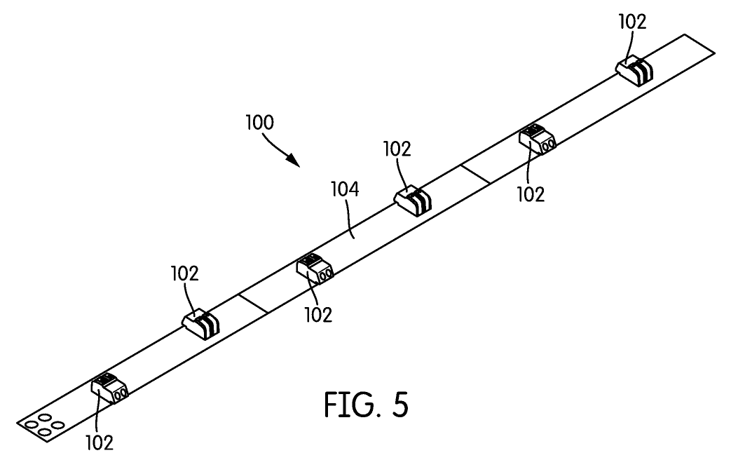

FIG. 5 is a perspective view of a flexible power connector strip, generally indicated at 100, according to yet another embodiment of the invention. In contrast to power connector strip 10 of FIGS. 1-4, power connector strip 100 of FIG. 5 has small terminal blocks 102 mounted on its PCB 104, instead of connectors. The terminal blocks 102 may be, for example, Wago 2060-452/998-404 surface-mount PCB terminal blocks (Wago Corporation, Minden, Germany). The terminal blocks 102 accept and capture bare wire leads, thus allowing elements that do not have connectors on them to connect to a power connector strip 100. Generally speaking, the connectors used in embodiments of the invention may be any types of connectors, although surface-mount connectors may be preferable in at least some embodiments.

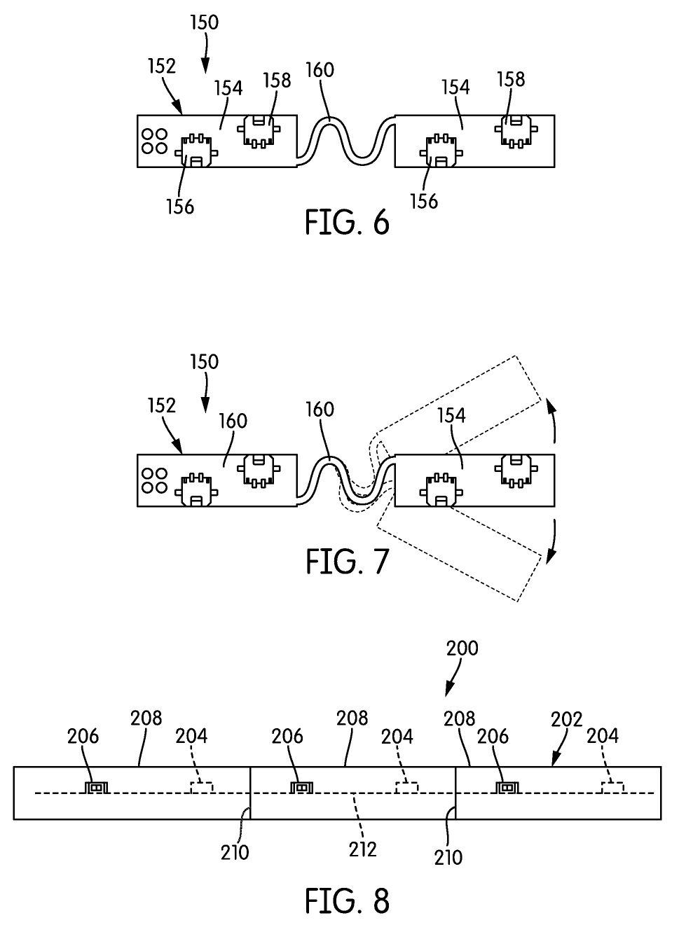

In the embodiments of FIGS. 1-5, the power connector strips 10, 100 are linear. As was described above, because they are flexible, they will bend out of the plane of FIG. 2. However, they will not bend in-plane. FIG. 6 is a top plan view of a power connector strip, generally indicated at 150, according to another embodiment of the invention. FIG. 6 illustrates a single repeating block 152. In the illustrated embodiment, the repeating block 152 has two individual units 154, each unit including two connectors 156, 158, although in other embodiments, there may be any number of units 154, and any number of connectors 156, 158 in each unit 154. The connectors 156, 158 face opposite directions, as do the connectors 14, 16 of the power connector strip 10 described above.

In power connector strip 150, the two units 154 are separated by a thinned, undulating strip of PCB material 160. The undulating strip 160 allows the power connector strip 150 to flex in plane, as illustrated in the top plan view of FIG. 7. Because the power connector strip 150 is flexible, it can also flex out-of-plane.

Typically, to make power connector strip 150, undulating conductive traces (for power and neutral or ground) would be defined in the metalization layer of a PCB, and then the undulating shape of the undulating strip 160 would be defined and cut around those conductive traces by a conventional cutting method, e.g., die cutting or laser cutting. The embodiment of FIGS. 6 and 7 shows an undulating strip 160 with a generally sinusoidal shape, but any thinned strip shape that allows for flexture in-plane may be used. Smooth curves may be less likely to act as crack initiators during flexture, but squared or triangular shapes could be used in the undulating strip as well.

Because of the reduced size of the undulating strip 160, it may have reduced ampacity relative to comparable conductive traces on a linear power conductor strip 10, 100. If additional current-carrying capacity is desirable or necessary, the PCB can be made with additional metalization layers to carry current, using vias to connect vertically-adjacent layers.

The embodiments shown in FIGS. 1-7 are primarily low-voltage embodiments. With low voltage, electrical insulation is less of a concern, and bare PCB can be used in most cases. However, as was noted briefly above, embodiments of the invention need not be limited to low voltage. FIG. 8 is a side elevational view of a power connector strip, generally indicated at 200, according to yet another embodiment of the invention. Power connector strip 200 is intended for use with high voltage.

The primary visible difference between power connector strip 200 and the low-voltage power connector strips 10, 100, 150 described above is an electrically insulative external covering, generally indicated at 202. The covering 202 is usually polymeric and flexible, and may be either transparent or opaque, depending on the embodiment. Suitable materials for the covering 202 include, e.g., PVC and EPDM polymers, although any electrically insulative material may be used, whether natural or synthetic. The particular materials that are used will depend on the voltage that power connector strip 200 carries, as well as the desired heat tolerance and flame ratings. Those heat tolerances and flame ratings may be dictated by electrical code or other regulatory standards.

Within the covering 202, the arrangement of power connector strip 200 is generally similar to its low-voltage counterparts, although the connectors and conductors would generally be rated for higher voltages and greater current-carrying capacities. In the illustrated embodiment, the covering 202 is opaque, although it may be transparent or translucent in other embodiments. Power connector strip 200 maintains the convention of having some connectors 204 face one direction and other connectors 206 face another direction; thus, in the view of FIG. 8, only connectors 206 are visible; the other connectors 204 are shown in phantom, as they are facing the other direction. However, as with other embodiments, any arrangement of connectors 204, 206 is possible.

Power connector strip 200 would typically maintain the same kind of architecture as its lower-voltage variants: repeating blocks divided into individual units, with each unit including one or more connectors. In power connector strip 200 of FIG. 8, three individual units 208 are shown, each unit including one left-facing connector 204 and one right-facing connector 206.

As with the embodiments described above, the units 208 of power connector strip 200 are separable, independent circuits that can be physically cut or divided from the other units 208. For the sake of convenience, on an opaque covering 202, the cut points 210 may be physically marked on the exterior of the covering 202. Alternatively, the portion of the covering 202 around a cut point 210 may be transparent to reveal cut-point markings on the encapsulated PCB 212.

Cutting a high-voltage power connector strip 200 may require additional steps. For example, after separating units 208 at their cut points, exposed ends of the units 208 may be sealed with electrically insulative material. This may involve adhering endcaps over the ends, potting the ends with an insulative compound, or applying some other insulator so that the resulting shortened power connector strip 200 is fully insulated. Depending on local safety regulations, cutting operations may be performed in the field by any installer, they may be restricted to properly trained personnel, or they may be restricted such that they are only done in the factory or by other trained and authorized entities.

In the description above, the electrical circuits involved are relatively simple. Contact traces on a flexible printed circuit board take the place of stranded copper wires or other, similar conductors. However, the units 19, 154, 208 may include more advanced circuitry and circuit components for some applications.

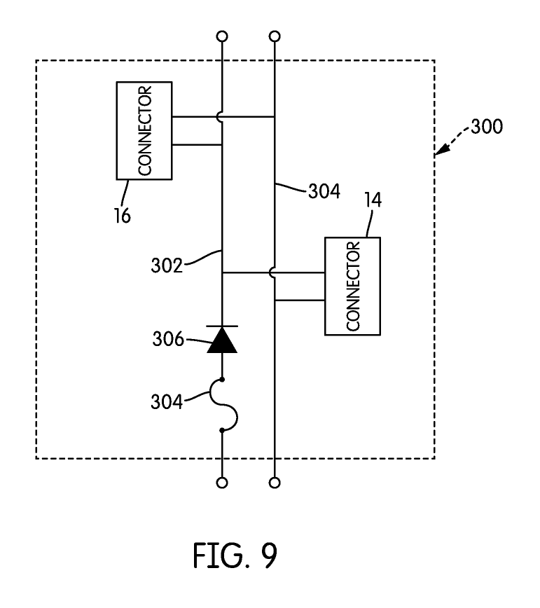

FIG. 9 is a circuit diagram of a unit, generally indicated at 300, that includes some additional circuit components beyond contact traces and conductors. As shown, the unit 300 has a pair of conductors 302, 304 that connect to connectors 14, 16. A fuse 304 is provided in series with one of the conductors 302. A diode 306 is also provided for polarity protection. In addition to the diode 306 for polarity protection, a transient voltage suppression (TVS) diode may also be provided in some embodiments. The fuse 304 and diode 306 may help to prevent electrical overload of connected components.

One advantage of simple-circuit power connector strips, like the power connector strip 10 described above, is that any connector 14, 16 can serve as the input and any connector 14, 16 can serve as the output. While adding additional circuit components to the individual units 19, 154, 208 may adapt them for special applications, it may also affect the ability of any connector 14, 16 to serve as either input or output. Still, the trade-off in functionality may be acceptable or even necessary in some embodiments.

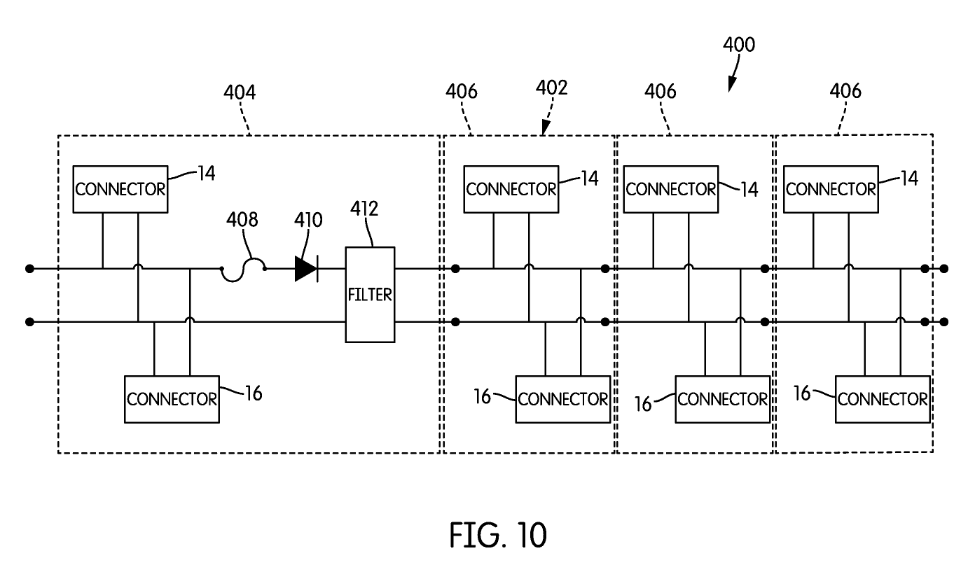

As more circuit components are added, the individual units may not be identical to each other. Instead, some units may be specialized. For example, a power connector strip may have a specialized input unit and a number of output units in the same strip. FIG. 10 is a circuit diagram of a power connector strip, generally indicated at 400, that embodies this concept. A single repeating block 402 is shown in FIG. 10; as with the other embodiments, there may be any number of repeating blocks 402 in the strip. The repeating block 402 has an input unit 404 and three output units 406.

The characteristics of the input unit 404 will vary with the particular application and the type of power that the power connector strip 400 is designed to accept. Specialized input units 404 may be particularly helpful, for example, where the incoming power is noisy or has unwanted voltage or current spikes. In these cases, it may be necessary or desirable to filter the power before it is output to the load. A specialized input unit 404 may also be helpful if the incoming power is AC power, but the load requires either DC power or a modified AC power with, e.g. a higher frequency.

In FIG. 10, the input unit 404 has two connectors 14, 16, arranged such that on the PCB, one connector 14 faces one direction, and the other connector 16 faces the other direction. While these connectors 14, 16 accept an input voltage, they may be identical to the other connectors. Alternatively, the input connectors 14, 16 may be of an entirely different type in order to avoid connecting output to input.

Beyond the input connectors 14, 16 in the input unit 404, a fuse 408 and polarity-protecting diode 410 are provided, as was described above with respect to FIG. 9. As with unit 300 of FIG. 9, a TVS diode may also be included. In addition to those basic overload-preventing components, the input unit 404 includes a filter 412 that receives its input from the input connectors 14, 16 and outputs to the output units 406 in the repeating block 402.

The filter 412 may be any type of filter, including a high-pass filter, a low-pass filter, or a band-pass filter. The cut-off frequency or frequencies for the filter 412 will differ from application to application. If AC power is to be converted to DC, or if a higher frequency is required, the input block 404 may also include a rectifier or other such components. Thus, the term “filter,” as used here, should be read broadly to encompass any components that alter the incoming power signal.

With respect to AC-to-DC conversion, U.S. Pat. No. 10,028,345, which is incorporated by reference in its entirety, discloses a number of different circuits for converting AC power to DC power on a flexible PCB, and for filtering the resulting power. Those circuits, or similar ones, may be used in embodiments of the invention. U.S. Pat. No. 10,028,345 discloses how to rectify and filter high-voltage AC power using a minimal number of components placed on a flexible PCB. The circuits typically comprise a rectifier and a simple passive capacitive filter, although some of the disclosed circuits do use a first-stage transistor-based capacitance multiplier and second-stage passive capacitive filters. However, the circuits of the '345 patent do not include a transformer to reduce the input voltage. Overall, the characteristics of the power-modifying components in the input unit 404 will vary with the embodiment, the application for which the power connector strip 400 is used, and the characteristics of the power that is required. The component 412 shown in FIG. 10 could, in essence, be a switched-mode power supply that converts from high-voltage AC to low-voltage DC.

The output units 406 are much like the units 19, 154, 208 of other embodiments: they have a number of connectors 14, 16. While the repeating block 402 of FIG. 10 has three output units 406, any number of output units 406 may be provided in a repeating block 402 or in the power connector strip 400 as a whole. Moreover, the units 404, 406 may be in any order in the repeating block, typically with more output units 406 than input units 404, although that need not always be the case. For example, the respective units 404, 406 may be arranged A-B-B-B, B-B-B-A, or in any other convenient fashion. It may also be helpful in some cases to include a single input unit 404 and a large number of output units 406.

If more output units 406 are needed without input units 404, the unneeded input units 404 could be severed from power connector strip 400 and the resulting separate strips of output units 406 could be connected together with cables using their connectors 14, 16. Alternatively, if the conductive contacts 22 of the repeating blocks 402 are accessible, repeating blocks 402 of the power connector strip 400 may be joined by connectors. For example, the connectors disclosed in U.S. Pat. 10,024,526, the contents of which are incorporated by reference in their entirety, may be suitable for connecting repeating blocks 402 using their conductive contacts 22.

As those of skill in the art will note, the input unit 404 of FIG. 10 includes only a single set of outputs, which are the outputs of the filter 412. In some embodiments, particularly if an input unit 404 is to be placed in the middle of a repeating block adjacent to an output unit 406 on each side, modifications to the input unit 404 may be helpful. For example, there may be two filters 412, one on each side of the input unit 404. Alternatively, there may be a single filter 412 with two sets of outputs, one going to each adjacent output unit 406.

While the invention has been described with respect to certain embodiments, the description is intended to be exemplary, rather than limiting. Modifications and changes may be made within the scope of the invention, which is defined by the appended claims.

What is claimed is:

1. A power connector strip, comprising:
an elongate, flexible printed circuit board defining therein a pair of conductors; and
a plurality of connectors mounted on the flexible printed circuit board, each of the plurality of connectors being electrically connected to the pair of conductors;
wherein the flexible printed circuit board is arranged such that it can be physically cut into independent functional units, each of the independent functional units including some of the plurality of connectors.

2. The power connector strip of claim 1, further comprising adhesive on a reverse side of the flexible printed circuit board.

3. The power connector strip of claim 1, wherein the power connector strip is comprised of a plurality of repeating blocks, each of the repeating blocks comprising
a section of the flexible printed circuit board;
one or more of the independent functional units;
a set of solder contacts for making an electrical connection with another section of the flexible printed circuit board; and
a set of alignment contacts adjacent to the set of solder contacts.

4. The power connector strip of claim 1, wherein the flexible printed circuit board comprises a plurality of sections of flexible printed circuit board connected together by overlapping solder joints.

5. The power connector strip of claim 1, wherein the connectors comprise terminal blocks.

6. The power connector strip of claim 1, wherein some of the plurality of connectors face a first direction, and others of the plurality of connectors face a second direction.

7. The power connector strip of claim 1, wherein portions of the flexible printed circuit board include thin, undulating portions, such that the power connector strip is capable of flexing in at least two planes.

8. The power connector strip of claim 7, wherein the thin, undulating portions are provided between respective independent functional units on the flexible printed circuit board.

9. The power connector strip of claim 1, wherein the power connector strip is encapsulated with a flexible, electrically insulating cover.

10. The power connector strip of claim 9, wherein the power connector strip carries high voltage.

11. The power connector strip of claim 1, wherein the independent functional units are electrically identical.

12. The power connector strip of claim 1, wherein at least some of the independent functional units comprise a fuse.

13. The power connector strip of claim 12, wherein at least some of the independent functional units comprise a diode in series with one of the pair of conductors.

14. The power connector strip of claim 1, wherein the independent functional units comprise input units and output units.

15. The power connector strip of claim 14, wherein the input units comprise filters.

16. The power connector strip of claim 1, wherein the flexible printed circuit board comprises therein a plurality of conductors, and each of the connectors is connected to each of the conductors.
